(19) United States
(12) Patent Application Publication
(10) Pub. No.: US 2003/0168249 A1
(43) Pub. Date: Sep. 11, 2003

(54) Wiring board and method for producing the same

(75) Inventors: Tatsuya Ito, Kakamigahara-shi (JP); Yukihiro Kimura, Nagoya-shi (JP)

Correspondence Address: SUGHRUE MION, PLLC, 2100 Pennsylvania Avenue, NW, Washington, DC, 20037-3213, US

(73) Assignee: NGK SPARK PLUG CO., LTD.

(21) Appl. No.: 10/365,438

(22) Filed: Feb. 13, 2003

(30) Foreign Application Priority Data
Feb. 14, 2002 (JP) P. 2002-036813

(51) Int. Cl. H05K 7/06

(52) U.S. Cl. 174/255

(57) ABSTRACT

A wiring board comprising: a metal core substrate shaped like a rectangle in plan view and having a front surface and a rear surface; and a buildup layer comprising an electrically insulating layer and a wiring layer, the buildup layer being formed on the front surface or the rear surface of the metal core substrate, wherein the metal core substrate has an extension formed on its side surface.

### FIELD OF THE INVENTION

The present invention relates to a wiring board including a metal core substrate and a method for producing such wiring boards.

### BACKGROUND OF THE INVENTION

An electrically insulating core substrate made of resin or a combination of resin and glass is used in a wiring board of a multilayer structure which has a plurality of electrically insulating layers, and a plurality of wiring layers located between the plurality of electrically insulating layers. In order to enhance the strength of the wiring board and prevent deformation such as warping of the wiring board, however, a metal core substrate, for example, made of a copper alloy is also used.

For example, as shown in FIG. 6A, a wiring board 30 including such a metal core substrate has: a metal core substrate 31 having a front surface 32 and a rear surface 33; through-holes 34 formed between the front and rear surfaces 32 and 33 of the core substrate 31 so as to pierce the core substrate 31; and a combination of a through-hole conductor 36 and a filler resin 37 disposed in each of the through-holes 34 through an electrically insulating material 35.

As shown in FIG. 6A, electrically insulating layers 38 and 39 are formed individually on the front and rear surfaces 32 and 33 of the metal core substrate 31 so as to be integrated with the electrically insulating material 35. Wiring layers 40 and 41 formed as predetermined patterns on surfaces of the electrically insulating layers 38 and 39 are connected to upper and lower ends of each through-hole conductor 36 and covered with electrically insulating layers 42 and 43 respectively. The wiring board 30 described above is one of wiring boards produced as follows. After a panel board including a plurality of core substrates 31 (product units) for providing a plurality of wiring boards 30 is produced, the panel board is cut by means of dicing or the like so as to be separated into the wiring boards 30 each having a size in accordance with each core substrate 31.

If each of the metal core substrates 31 is thick, there is fear that burrs caused by cutting may be exposed on each of side surfaces of the obtained wiring boards 30 as well as it may be difficult to perform dicing efficiently and accurately.

In order to solve these drawbacks, as shown in FIG. 6B, a wiring board 30a like the wiring board 30 has been examined. The wiring board 30a uses a metal core substrate 31a. The metal core substrate 31a is one of metal core substrates produced as follows. A metal plate 31b for providing a plurality of metal core substrates as shown in FIG. 6C is cut along cutting-projected lines S to thereby produce the metal core substrates 31a. A thin portion 31c is formed between adjacent ones 31a and 31a of the core substrates in advance.

Accordingly, when the metal plate 31b is cut along the cutting-projected lines S after through-hole conductors 36, electrically insulating layers 38, 39, 42 and 43, wiring layers 40 and 41, etc. are formed on each core substrate 31a, wiring boards 30a can be obtained so that cut surfaces of the thin portions 31c are exposed on side surfaces of each wiring board 30a as shown in FIG. 6B.

### SUMMARY OF THE INVENTION

It is however necessary to perform a finishing process for removing burrs because an end surface of each thin portion 31c of the core substrate 31a is also exposed along the whole length of a corresponding side surface of the wiring board 30a. Hence, there is a problem that unintended electrical connection to the outside or unintended electric connection in the inside of the wiring board is apt to be caused.

Further, when the metal plate 31b is cut into wiring boards 30a individually and separately, it is necessary to apply dicing or the like to the whole length of each of the thin portions 31c of the core substrate 31a in four side surfaces of each wiring board 30a. For this reason, there is another problem that extra man-hour and time are required as well as burrs are apt to be generated on respective side surfaces of the obtained wiring board 30a.

In order to solve the problems described in the related art, an object of the invention is to provide a wiring board which need not be subjected to a finishing process or the like and has little possibility that unintended electrical connection to the outside and unintended electrical connection in the inside of the wiring board may be caused, and a method for producing such wiring boards efficiently.

In order to solve the problems, the invention is developed with an idea that slits and connection tie-bars are disposed between adjacent ones of core substrates in a panel board which includes a metal plate having a plurality of metal core substrates and which is prepared for providing a plurality of wiring boards.

That is, according to an aspect of the invention (claim 1), there is provided a wiring board including a metal core substrate shaped like a rectangle in plan view and having a front surface and a rear surface, and at least one buildup layer constituted by a combination of at least one electrically insulating layer and at least one wiring layer and formed on at least one of the front surface and the rear surface of the metal core substrate, wherein the metal core substrate has extensions formed on its side surfaces.

According to this aspect, the extensions of the metal core substrate contained in the wiring board are merely partially exposed on the side surfaces of the wiring board. In other words, the metal core substrate has a contour smaller than that of the outer side surfaces of the wiring board, so that the metal core substrate is embedded in the wiring board. As a result, a finishing process such as burr removal or polishing may be dispensed with or may be reduced as much as possible, and the possibility that unintended electrical connection to the outside may be caused can be reduced. Hence, the wiring board can be obtained as a wiring board high in reliability.

Incidentally, as the material of the metal core substrate, for example, there may be used a copper alloy such as Cu-2.3 wt %Fe-0.03 wt %P (194 alloy), pure copper, oxygen-free copper, or an Fe—Ni alloy such as Fe-42 wt %Ni (42 alloy) or Fe-36%Ni (Invar). The metal core substrate may be also used as ground potential.

In this specification, the concept “buildup layer” means a laminated portion constituted by a combination of at least one electrically insulating layer and at least one wiring layer. The concept “buildup layer” may include a structure obtained by further lamination of at least one new electrically insulating layer and at least one new wiring layer on the aforementioned laminated portion, that is, a structure constituted by a combination of a plurality of electrically insulating layers and a plurality of wiring layers located between the plurality of electrically insulating layers.

In addition, according to this aspect, there may be also provided a wiring board including a metal core substrate shaped like a rectangle in plan view and having a front surface and a rear surface, and at least one buildup layer constituted by a combination of at least one electrically insulating layer and at least one wiring layer and formed on at least one of the front surface and the rear surface of the metal core substrate, wherein the metal core substrate has extensions formed on its side surfaces so that the extensions are partially exposed 6 in side surfaces of the wiring board.

According to this aspect, there may be further provided a wiring board including a metal core substrate shaped like a rectangle in plan view and having a front surface and a rear surface, at least one buildup layer constituted by a combination of at least one electrically insulating layer and at least one wiring layer and formed on at least one of the front surface and the rear surface of the metal core substrate, and through-hole conductors formed between the front and rear surfaces of the metal core substrate through an electrically insulating material so as to pierce the metal core substrate, wherein the metal core substrate has extensions formed integrally with its side surfaces.

According to another aspect of the invention (claim 5), there is provided a method of producing wiring boards, including the steps of: forming tie-bars and slits along boundaries which set a plurality of product areas in a metal plate shaped like a rectangle in plan view and having a front surface and a rear surface, in the condition that the plurality of product areas will be formed as metal core substrates in terms of product units; producing a panel board having the product units by forming at least one buildup layer constituted by a combination of at last one electrically insulating layer and at least one wiring layer on at least one of the front surface and the rear surface of the metal plate in which the tie-bars and the slits are formed; and cutting the panel board along the boundaries to separate the panel board into wiring boards in accordance with the product units.

According to this aspect, the panel board for providing a plurality of wiring boards can be cut into the wiring boards separately and individually by a simple operation of cutting off the tie-bars partially located in the boundaries of adjacent ones of the metal core substrates. As a result, the wiring boards can be produced efficiently and occurrence of burrs or the like in the side surfaces of each wiring board can be eliminated or reduced. In addition, a cutting jig such as a dicing blade used in the cutting step can be restrained from being damaged.

Incidentally, each of the tie-bars may be set to be as thick as the metal plate or may be set to be thinner than the metal plate so that the wiring boards can be produced with higher efficiency.

In addition, according to this aspect, there may be also provided a method of producing wiring boards, including the steps of: forming tie-bars and slits along boundaries which set a plurality of product areas in a metal plate shaped like a rectangle in plan view and having a front surface and a rear surface, in the condition that the plurality of product areas will be formed as metal core substrates in terms of product units; disposing through-hole conductors between the front and rear surfaces of each core substrate through an electrically insulating material so that the through-hole conductors are located in predetermined positions in accordance with each metal core substrate; producing a panel board having the product units by forming at least one buildup layer constituted by a combination of at last one electrically insulating layer and at least one wiring layer on at least one of the front surface and the rear surface of the metal plate in which the tie-bars and the slits are formed; and cutting the panel board along the boundaries to separate the panel board into wiring boards in accordance with the product units.

### BRIEF DESCRIPTION OF THE DRAWING

[FIG. 1]

FIG. 1 is a sectional view showing a wiring board according to the invention.

[FIG. 2]

FIG. 2 is a sectional view taken along line A-A in FIG. 1.

[FIG. 3]

FIGS. 3A and 3B are schematic views showing steps in a producing method according to the invention.

[FIG. 4]

FIGS. 4A to 4D are schematic views showing steps following FIG. 3B in the producing method according to the invention.

[FIG. 5]

FIG. 5A is a plan view showing a metal plate according to a modified example of the invention; and FIGS. 5B and 5C are sectional views taken along the lines B-B and C-C in FIG. 5A.

[FIG. 6]

FIGS. 6A and 6B are sectional views showing a wiring board in the related art; and FIG. 6C is a sectional view showing a metal plate used for wiring boards each shown in FIG. 6B.

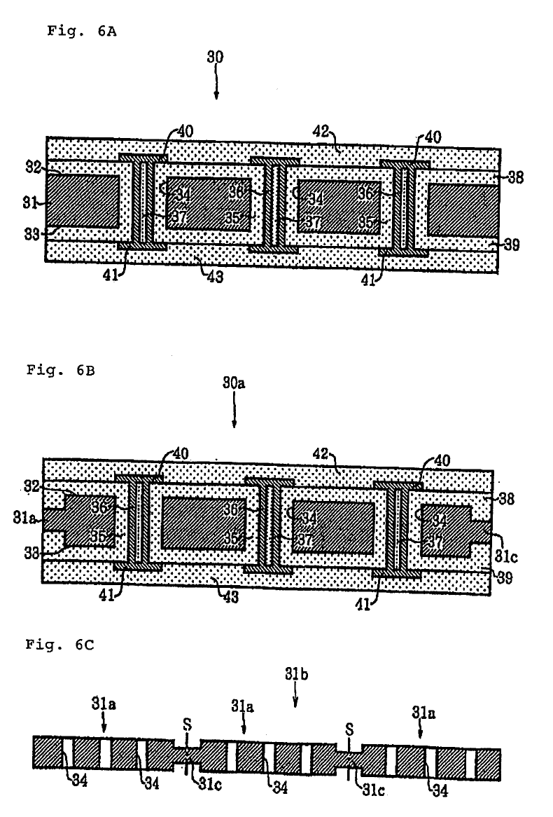

[Description of the Reference Numbers and Signs]

1 . . . wiring board
2 . . . metal core substrate
2b, 2b′ . . . metal plate
2d . . . slit
3 . . . extension
3a to 3d . . . tie-bar
4 . . . front surface
5 . . . rear surface
10, 11, 14, 15 . . . electrically insulating layer
12, 13, 18, 19 . . . wiring layer
BU . . . buildup layer

### DETAILED DESCRIPTION OF THE INVENTION

A preferred embodiment of the invention will be described below with reference to the drawings.

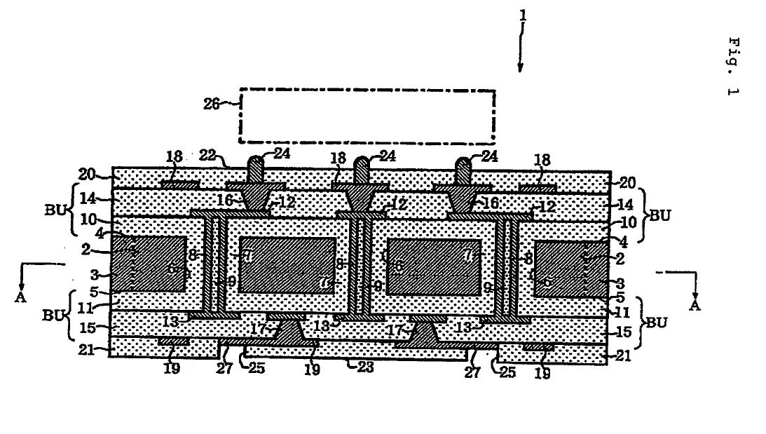

FIG. 1 shows a vertical section of a wiring board 1 according to the invention.

In FIG. 1, the wiring board 1 has: a metal core substrate 2 shaped like a square (rectangle) in plan view; electrically insulating layers 10, 14, 20, 11, 15, and 21 formed on the front surface 4 and the rear surface 5 (the surface illustrated on the lower side) of the core substrate 2; and wiring layers 12, 18, 13 and 19 located between the electrically insulating layers 10, 14, 20, 11, 15 and 21 and having predetermined patterns.

The metal core substrate 2 is about 0.25 μm thick and, for example, made of the same copper alloy as described above. Each of the electrically insulating layers 10, 11, 14 and 15 is about 30 μm thick and, for example, made of an epoxy resin containing an inorganic filler such as a silica filler. Each of the electrically insulating layers (solder resist layers) 20 and 21 located as the uppermost layer and the lowermost layer is about 25 μm thick and made of the same resin as that for the electrically insulating layers 10, 11, 14 and 15. Each of the wiring layers 12, 13, etc. is constituted by a copper-plating layer about 15 μm thick.

Incidentally, the electrically insulating layers 10 and 14 and the wiring layers 12 and 18 located on the upper side form a buildup layer (BU) while the electrically insulating layers 11 and 15 and the wiring layers 13 and 19 located on the lower side form another buildup layer (BU).

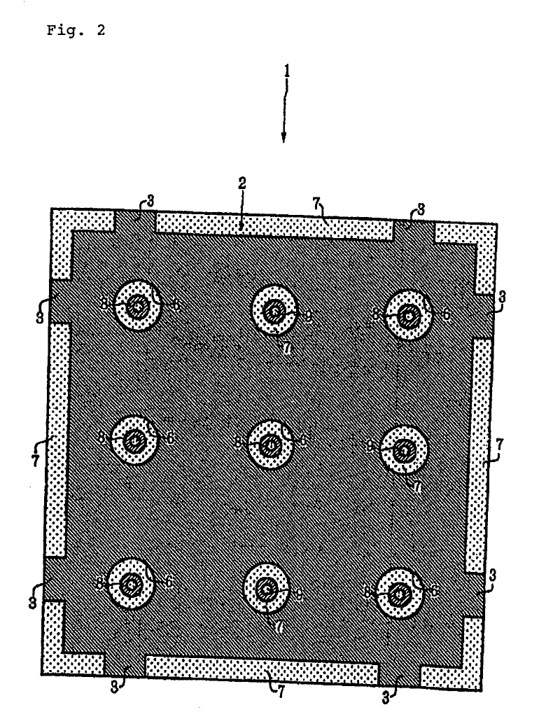

Further, as shown in FIGS. 1 and 2, an electrically insulating material 7 is formed in the outer circumference of the metal core substrate 2. As a result, the metal core substrate 2 is encircled by the outer circumference of the wiring board 1. Two extensions 3 are provided on each side of the metal core substrate 2 so as to be integrated with the metal core substrate 2 and extruded from the side. End surfaces of the extensions 3 are exposed on each side surface of the wiring board 1. As will be described later, the extensions 3 are provided for partially connecting adjacent ones 2 and 2 of the metal core substrates in a metal plate which includes a plurality of metal core substrates 2 and which is prepared for providing a plurality of wiring boards. The extensions 3 remain when tie-bars are cut off to separate the metal plate into the plurality of wiring boards 1 after the plurality of wiring boards 1 are formed. Incidentally, as shown FIG. 2, the electrically insulating material 7 is disposed in positions of the respective side surfaces of the wiring board 1 except the extensions 3. FIG. 2 shows a section taken along line A-A in FIG. 1.

Further, as shown in FIGS. 1 and 2, a plurality of circular through-holes 6 about 250 μm in inner diameter are formed in predetermined positions of the metal core substrate 2 between the front and rear surfaces 4 and 5 so as to pierce the metal core substrate 2. Each of the through-holes 6 is filled with the electrically insulating material 7 integrated with the electrically insulating layers 10 and 11 while a through-hole conductor 8 having a diameter of about 100 μm is formed in the center portion of each through-hole 6. In each through-hole 6, the electrically insulating material 7 and the through-hole conductor 8 are concentric with each other 1 so as to pass through the metal core substrate 2.

Each through-hole conductor 8 is connected to the wiring layers 12 and 13 formed on surfaces of the electrically insulating layers 10 and 11 at the upper and lower ends of the through-hole conductor 8, respectively.

As shown in FIG. 1, via-conductors (filled via-conductors) 16 are formed in the electrically insulating layer 14 between the wiring layers 12 and 18 above the front surface 4 of the metal core substrate 2 so that the wiring layers 12 and 18 are connected with each other by the via-conductors 16. A plurality of solder bumps (IC connecting terminals) 24 are formed in predetermined positions on the wiring layer 18 so as to pass through the electrically insulating layer (solder resist layer) 20 as the uppermost layer and protrude out from a first main surface 22. Each of the solder bumps 24 is made of a low-melting alloy such as an Sn—Ag alloy, an Sn—Ag—Cu alloy, an Sn—Cu alloy, an Sn—Zn alloy, or a Pb—Sn alloy. (In this embodiment, an Sn—Ag alloy is used.) As shown FIG. 1, the solder bumps 24 are individually connected to connection terminals (not-shown) of an IC chip 26 mounted on the first main surface 22. Incidentally, the solder pumps 24 and the connection terminals of the IC chip 26 are protectively covered with an underfill material not shown.

On the other hand, as shown in FIG. 1, via-conductors 17 are also formed in the electrically insulating layer 15 between the wiring layers 13 and 19 below the rear surface 5 of the metal core substrate 2 so that the wiring layers 13 and 19 are connected to each other by the via-conductors 17. Further, wires 27 extending from the wiring layer 19 are located on the bottom surface of opening portions 25 provided in the electrically insulating layer (solder resist layer) 21 serving as the lowermost layer and are exposed on a second main surface 23 side.

The wires 27 are plated with Ni and Au and used as connection terminals for a not-shown printed board such as a mother board on which the wiring board 1 per se is mounted. Incidentally, solder balls or conductor pins made of a copper or iron alloy maybe joined to the surfaces of the wires 27.

According to the wiring board 1 configured as described above, the extensions 3 obtained by cutting off the tie-bars of the metal plate used at the time of production are exposed on the surface sides of the wiring board 1. Since the area of each of the extensions 3 is small, a finishing process such as burr removal or polishing can be dispensed with or minimized and the possibility that unintended electrical connection to the outside or unintended electrical connection in the inside of the wiring board 1 may occur can be also reduced. Accordingly, reliability of the wiring board 1 can be enhanced. Further, since the side surfaces of the wiring board 1 except the extensions are covered with the electrically insulating material, the area of metal exposed on the side surfaces can be reduced so that a drawback caused by corrosion from the side surfaces can be reduced, and delaminations and migrations caused by moisture absorbed through an interface between metal (the extensions) and resins can be prevented.

A method of producing such wiring boards 1 will be described below.

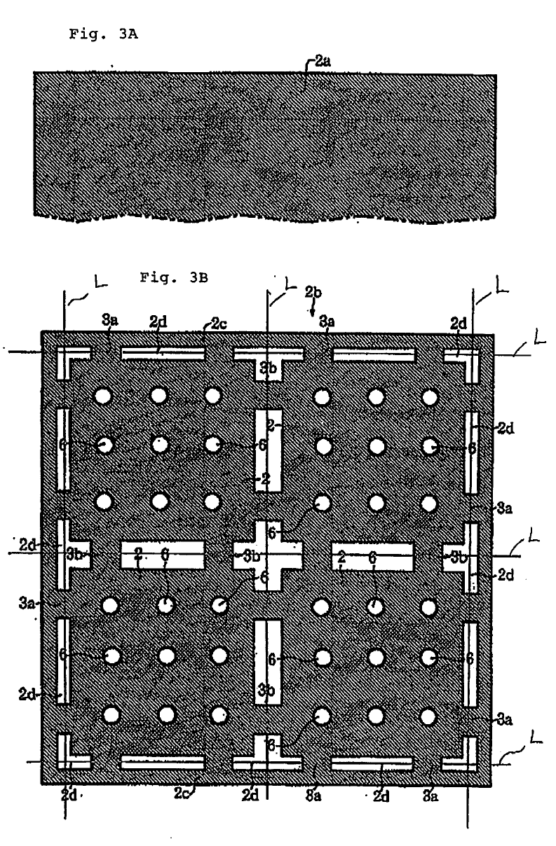

FIG. 3A shows a part of a naked metal plate 2a made of Cu-2.3 wt %Fe-0.03 wt %P (194 alloy) as a copper alloy with a thickness of about 0.25 mm and shaped like a square (rectangle) in plan view. Photosensitive resin layers not shown are formed on the front and rear surfaces of the naked metal plate 2a. After each of the photosensitive resin layers is exposed to light and developed with a predetermined pattern, it is etched. As a result, as shown in FIG. 3B, a metal plate 2b having four metal core substrates 2 in total (that is, two metal core substrates 2 by two metal core substrates 2), a rectangular frame-shaped edge portion 2c located on the outer side to surround the four metal core substrates 2, tie-bars 3b for tying adjacent ones 2 and 2 of the metal core substrates to each other, and tie-bars 3a for tying the edge portion 2c to the metal core substrates 2 adjacent to the edge portion 2c is formed in accordance with the pattern (the step of forming tie-bars and slits).

Slits 2d each shaped like a rectangle, a nearly cross or a nearly L figure in plan view are located in portions surrounded by adjacent ones 2 and 2 of the metal core substrates and the tie-bars 3b and in portions surrounded by the edge portion 2c and the metal core substrates 2 and the tie-bars 3a adjacent to the edge portion 2c. Each of the slits 2d is selected to have a size (width) of 0.4 mm in a direction perpendicular to a boundary (cutting-projected line L) corresponding to each product unit. The width of each slit 2d is selected to be larger than the thickness of a cutting edge which will be used for cutting the panel board along the boundaries. When the size relation is selected as described above, the cutting edge can be prevented effectively from being abraded or damaged. In consideration of positional displacement of the cutting edge from the cutting-projected line on the panel board, it is preferable that the width of each slit is set to be larger by at least 0.05 mm than the thickness of the cutting edge.

Further, in order to prevent the cutting edge effectively from being abraded or damaged, it is preferable that the size (length) of each slit 2d in a direction parallel to the boundary (cutting-projected line L) is selected to be larger than the size (width) of each tie-bar in a direction parallel to the boundary (cutting-projected line).

Further, a plurality of through-holes 6 are formed simultaneously in predetermined positions of each metal core substrate 2.

That is, in the metal plate 2b, tie-bars 3b and slits 2d are formed along boundaries between adjacent ones 2 and 2 (product areas) of the core substrates as the product units while tie-bars 3a and slits 2d are formed along boundaries between the core substrates 2 and the edge portion 2c.

Incidentally, in place of etching applied to the naked metal plate 2a, laser machining or punching due to pressing may be employed.

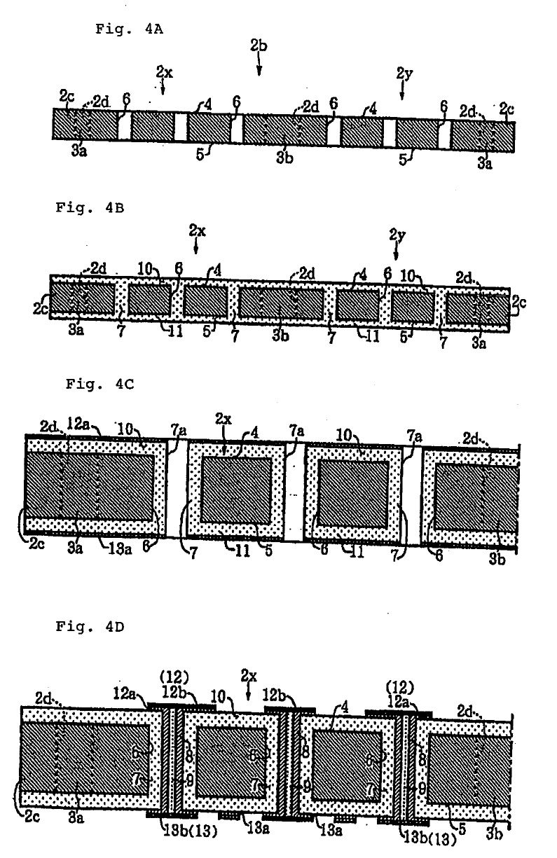

FIG. 4A shows a vertical section of a metal plate 2b configured as described above and having metal core substrates 2x and 2y each having a front surface 4 and a rear surface 5. Incidentally, for convenience' sake, front and rear surfaces of the metal plate 2b will be also referred to as “front surface 4” and “rear surface 5” respectively.

Next, a resin film about 50 μm thick is disposed on each of the front and rear surfaces 4 and 5 of the metal plate 2b and thermo-compression-bonded thereto in a direction of thickness of the metal plate 2b. As a result, as shown in FIG. 4B, electrically insulating layers 10 and 11 each about 30 μm are formed on the front surface 4 of the metal plate 2b and under the rear surface 5 of the metal plate 2b respectively. At the same time, the through-holes 6 formed in each metal core substrate 2 are filled with an electrically insulating material 7 constituted by part of each resin film which is solidified after entering the through-holes 6. Alternatively, a roll coater may be used for applying a liquid resin on the front and rear surfaces 4 and 5 of the metal plate 2b so that the electrically insulating layers 10 and 11 and the electrically insulating material 7 are formed on the front and rear surfaces 4 and 5 of the metal plate 2b while the through-holes 6 are filled with the electrically insulating material 7.

Next, a neighbor of the center of the electrically insulating material 7 in each of the through-holes 6 in the metal core substrates 2x and 2y of the metal plate 2b is irradiated with a laser beam (e.g. carbon dioxide laser beam) along the direction of thickness of the metal plate 2b. As a result, as illustrated as the core substrate 2x in FIG. 4C, through-holes 7a each having an inner diameter of about 100 μm are formed so as to pierce the electrically insulating layers 10 and 11 and the electrically insulating material 7. Incidentally, copper foil sheets 12a and 13a are attached onto the electrically insulating layers 10 and 11 respectively in advance.

Further, after a plating catalyst containing Pb is applied onto the inner walls of the through-holes 7a, the inner walls of the through-holes 7a are electrolessly plated with copper or electroplated with copper. As a result, as shown in FIG. 4D, nearly columnar through-hole conductors 8 are formed in the through-holes 7a respectively. The inside of each through-hole conductor 8 is filled with a filler resin 9 made of an epoxy resin containing a silica filler or the like.

Next, the whole surfaces of the upper and lower copper foil sheets 12a and 13a are electroplated with copper (12b and 13b). The same photosensitive resin as described above is applied on the copper-plating layers 12b and 13b. After the photosensitive resin is exposed to light and developed with a predetermined pattern, it is etched (known subtractive method).

As a result, as shown in FIG. 4D, wiring layers 12 and 13 following the predetermined pattern are formed on the electrically insulating layers 10 and 11 while respective portions just above the filler resin 9 are covered and plated.

Then, electrically insulating layers 14 and 15 and wiring layers 18 and 19 which are combined with the electrically insulating layers 10 and 11 and the wiring layers 12 and 13 to constitute buildup layers (BUs) are formed by a known buildup process (such as a semi-additive method, a full additive method, a subtractive method, a method of forming electrically insulating layers by lamination of film-like resin materials, or a photolithographic technique) (the step of forming at least one buildup layer).

Further, as described above with reference to FIG. 1, the electrically insulating layer 20 and the solder bumps 24 are formed on the upper buildup layer BU while the electrically insulating layer 21, the opening portions 25 and the wires 27 are formed on the lower buildup layer BU. Thus, the production of the panel board having the plurality of product units is completed.

Finally, a not-shown dicing blade having a cutting edge about 0.3 mm thick is used so that the panel board is cut along the boundaries of the metal core substrates 2 and 2 in the metal plate 2b embedded in the panel board so that the tie-bars 3a and 3b are cut off at their central positions (the step of cutting the panel board). As a result, a plurality of wiring boards 1 each having the sectional structure as shown in FIG. 1 can be obtained at once. Incidentally, extensions 3 and 3 located on each side surface of each wiring board 1 are part of the tie-bars 3a and 3b remaining after the cutting step.

According to the method of producing wiring boards 1, the wiring boards 1 can be produced efficiently and occurrence of burrs can be eliminated or reduced because each of end surfaces of the extensions 3 exposed on side surfaces of each wiring board 1 has a small area. In addition, this method contributes to suppression of damage or abrasion of a cutting jig such as a dicing blade used in the cutting step to improve the durability of the cutting jig.

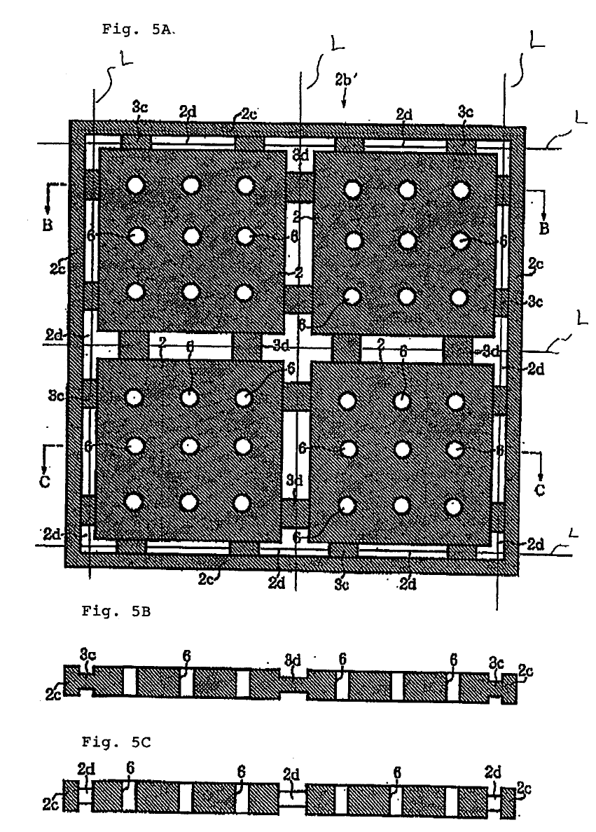

FIGS. 5A, 5B and 5C relate to a metal plate 2b′ as an applied example of the metal plate 2b.

Likewise, the metal plate 2b′ has: four metal core substrates 2 in total (that is, two metal core substrates 2 by two metal core substrates 2); a rectangular frame-shaped edge portion 2c located on the outer side to surround the meal core substrates 2; tie-bars 3d for tying adjacent ones 2 and 2 of the metal core substrates to each other; and tie-bars 3c for tying the edge portion 2c to the metal core substrates 2 adjacent to the edge portion 2c, as shown in FIGS. 5A to 5C. That is, the metal plate 2b′ has the same configuration as the metal plate 2b except that each of the tie-bars 3c and 3d in the metal plate 2b′ is set to be thinner than each of the metal core substrates 2 and the edge portion 2c.

In order to obtain the metal plate 2b′, for example, only portions of the naked metal plate 2a for forming the tie-bars 3c and 3d and slits 2d adjacent to the tie-bars 3c and 3d are etched to be long and narrow so that concave grooves each having a depth in a range of from the order of tens of μm to the order of hundreds of μm are formed in advance. Then, etching, laser machining or punching due to pressing is applied to the naked metal plate 2a in accordance with a predetermined pattern. Thus, the metal plate 2b′ can be obtained. Incidentally, the concave grooves may be formed only in a single surface of the naked metal plate 2a or may be provided only in positions where the tie-bars 3c and 3d will be formed later. When a panel board including such a metal plate 2b′ is used, the cutting step can be performed more efficiently. Further, because the area of each of the extensions exposed from the side surfaces of wiring boards after separation can be reduced more greatly, the drawback caused by corrosion from the side surfaces can be suppressed as much as possible.

The invention is not limited to the embodiment and its applied example described above.

The extensions 3 exposed on the side surfaces of each wiring board 1 may be constituted by four tie-bars formed in the central portions of the side surfaces respectively or may be constituted by twelve narrow tie-bars which are formed so that three tie-bars are provided on each side surface.

Further, the buildup layer BU may be formed only on the front surface 4 of each metal core substrate 2 or only on the rear surface 5 of each metal core substrate 2.

Further, each metal core substrate or the metal plate may be shaped like a rectangle in plan view.

Besides the copper alloy or Fe—Ni alloy as described above, pure copper, oxygen-free copper, any kind of steel material, titanium, a titanium alloy, aluminum, an aluminum alloy, etc. may be used as the material for forming the metal core substrate 2 and the metal plates 2b and 2b′.

Further, the plurality of metal core substrates 2 formed in each metal plate 2b or 2b′ may be formed so that the number of rows of metal core substrates is different from the number of columns of metal core substrates.

As described above, the material of each of the electrically insulating layers 14, 15, etc. may contain the epoxy resin as a main component. Alternatively, a resin such as a polyimide resin, a BT resin or a PPE resin having the same heat resistance and pattern formability as the epoxy resin may be used as the material or a composite resin material which is formed in a such a manner that a fluororesin of a three-dimensional network structure such as PTFE having continuous pores is impregnated with a resin such as an epoxy resin may be used as the material. Incidentally, besides the thermo-compression bonding of an electrically insulating resin film, a method of applying a liquid resin by use of a roll coater may be used for forming each electrically insulating layer. In addition, the composition of glass cloth or a glass filler mixed with each electrically insulating layer may be one member selected from the group consisting of E-glass, D-glass, Q-glass and S-glass, or may be a combination of two or more members selected from the group.

Further, besides the copper (Cu) plating layer, an Ag plating layer, an Ni plating layer, an Ni—Au plating layer, or the like may be used as the material of the wiring layers 12, etc. or the through-hole conductors 16. Alternatively, the material of the wiring layers 12, 6 etc. or the through-hole conductors 16 may be formed by a method of applying an electrically conductive resin without use of these metal plating layers.

In addition, the via-conductors may be formed as filled via-conductors 16 or may be formed as conformal via-conductors each of which is shaped like an inverted cone and is not fully filled with a conductor internally. Alternatively, the via-conductors may be provided in the staggered form in which via-conductors are stacked little by little while the axial centers of the via-conductors are shifted, or may be provided in the form in which a wiring layer extending in directions on a plan is interposed in the middle.

According to a wiring board according to the invention as described above, extensions provided on the outer circumference of each embedded metal core substrate are exposed merely partially on side surfaces of each wiring board. Accordingly, a finishing process such as burr removal or polishing can be dispensed with or may be required as less as possible. Because the extensions can reduce the possibility that unintended electrical connection to the outside or unintended electrical connection in the inside of the wiring board may occur, reliability of the wiring board can be improved.

According to a method of producing wiring boards according to the invention, a panel board having a metal plate embedded therein and prepared for providing a plurality of wiring boards is formed so that metal core substrates in product units are disposed to be lower from boundaries (cutting-projected line L). Accordingly, the panel board can be cut into wiring boards separately and individually by a simple operation of cutting off tie-bars which are located in the boundaries of adjacent ones of the metal core substrates and which are formed so as to be laid over the boundaries of products. Accordingly, the wiring boards can be produced efficiently and occurrence of burrs on the side surfaces of each wiring board can be eliminated or reduced. In addition, a cutting jig used in the cutting step can be restrained from being damaged.

This application is based on Japanese Patent application JP 2002-36813, filed Feb. 14, 2002, the entire content of which is hereby incorporated by reference, the same as if set forth at length.

What is claimed is:

1. A wiring board comprising:
a metal core substrate shaped like a rectangle in plan view and having a front surface and a rear surface; and
a buildup layer comprising an electrically insulating layer and a wiring layer, the buildup layer being formed on the front surface or the rear surface of the metal core substrate,
wherein the metal core substrate has an extension formed on its side surface.

2. The wiring board according to claim 1, wherein the extension is exposed from a surface of the wiring board.

3. The wiring board according to claim 1, wherein the extension is thinner than any other portion of the metal core substrate.

4. The wiring board according to claim 2, wherein the extension is thinner than any other portion of the metal core substrate.

5. A method for producing a wiring board comprising the steps of:
forming tie-bars and slits along boundaries which set a plurality of product areas respectively in a metal plate shaped like a rectangle in plan view and having a front surface and a rear surface, in a condition that the plurality of product areas are to be formed as metal core substrates in terms of product units;
producing a panel board having the product units by forming at least one buildup layer comprising an electrically insulating layer and a wiring layer on at least one of the front surface and the rear surface of the metal plate in which the tie-bars and the slits are formed; and
cutting the panel board along the boundaries to separate the panel board into wiring boards in accordance with the product units.

6. The method according to claim 5, wherein a cutting edge having a thickness smaller than a width of each of the slits in a direction perpendicular to the boundaries is used in the step of cutting the panel board.

7. The method according to claim 5, wherein the slits are formed so that a size of each of the slits in a direction parallel to the boundaries is larger than a size of each of the tie-bars in a direction parallel to the boundaries.

8. The method according to claim 6, wherein the slits are formed so that a size of each of the slits in a direction parallel to the boundaries is larger than a size of each of the tie-bars in a direction parallel to the boundaries.
